(19) United States
(12) Patent Application Publication
(10) Pub. No.: US 2008/0008337 A1
(43) Pub. Date: Jan. 10, 2008

(54) USB HUB WITH A USB POWERED SPEAKER

(76) Inventor: Kwang-Hwa Liu, Sunnyvale, CA (US)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,170

(22) Filed: Jul. 5, 2006

(51) Int. Cl. H03F 21/00

(52) U.S. Cl. 381/120

(57) ABSTRACT

A USB hub with a USB powered speaker is provided. This combinational apparatus comprises a USB hub controller, an amplifier stage and a volume controller. The USB hub controller controls a first USB socket and a second USB socket. The first USB socket connects an upstream USB device providing a voltage source. The second USB socket connects a downstream USB device powered by the voltage source. The amplifier stage is also powered by the same voltage source and drives a speaker according to an audio input signal. The volume controller provides a volume signal to control the gain of the amplifier stage. When the total current output by the voltage source is larger than a predetermined value, the volume signal changes in response to the total current.

### BACKGROUND OF THE INVENTION

1. Field of the Invention

The present invention relates to a speaker powered by a universal serial bus (USB). More particularly, the present invention relates to a USB hub with a A USB powered speaker.

2. Description of the Related Art

USB has become one of the most prevalent interface standards for computer peripherals, such as mouse-like pointing devices, keyboards, memory cards, printers, digital cameras, personal data assistants (PDA), and even cellular phones.

A typical personal computer offers several USB ports (sockets) on its chassis. However, most PCs are placed underneath a desk or in an out-of-reach location. With the proliferation of USB peripherals, it is highly desirable to have an USB hub on a convenient location to the PC user, preferably on the vicinity of the keyboard and mouse.

Further, many PCs, especially those for home users, are equipped with a pair of speakers for the audio output of the computer. In the past, those PC speakers use their own AC-DC adapters to generate a supply voltage for its audio power amplifier to drive the speakers. But with the recent improvement of class-D audio power amplifiers, it has opened up the market for USB-powered PC speakers.

Since PC speakers and the USB hub are generally placed on the desk top, in the vicinity of the keyboard, it is natural to conceive of a product that is the combination of a USB hub and a USB-powered speaker or a USB-powered speaker set. This combinational apparatus can eliminate the requirement and the cost for an AC adapter used by conventional PC speakers. It can also eliminate the space and cost associated with a separate USB hub case.

FIG. 1 is a schematic diagram showing a typical combinational apparatus 120 comprising a USB hub and a USB-powered speaker. USB port 114 of host computer 110 supplies power to support USB hub controller 130, its down stream USB sockets 132-138, as well as a USB-powered amplifier stage 122. USB powered amplifier stage 122 drives a representative speaker 124 (typically it will be a pair of speakers). Volume controller 126 sets the output power level of amplifier stage 122 by dividing reference voltage V11 output by amplifier stage 122 and providing voltage V12 back to amplifier stage 122. As can be seen, voltage V12 is a component of reference voltage V11 and is produced by the voltage divider circuit comprising resistors 127 and 128, in which resistor 127 is fixed and resistor 128 is variable. The resistance of variable resistor 128 can be adjusted to control the magnitude of voltage V12. Voltage V12 controls the gain of amplifier stage 122 and therefore controls the output power level of amplifier stage 122.

According to the USB standard specifications, an USB port can deliver up to a power of 0.5 A by 5.0V to a down-stream device or a down-stream hub. Thus the combinational apparatus of a USB hub and a set of USB-powered speakers may overload a host computer's USB port. If too many peripherals are plugged into the USB hub while the speaker is turned on at the same time, it creates an overload condition. This will trigger the overload protection device of the host computer's USB port to shut down the supply voltage, interrupting the proper operation of some or all USB peripherals connecting to this hub.

In the combinational apparatus 120 mentioned above, there is no mechanism to prevent overload conditions from happening. The upstream USB port 114 may react to an over-current condition and shut down completely the supply voltage VDD to the combinational apparatus 120.

### SUMMARY OF THE INVENTION

Based on the situation described above, it is desirable that a control circuit can roll back the current and power consumption of a secondary USB load, such as the USB-powered speaker, in the event of imminent overload condition, thus making more current available to other critical loads connected to the USB hub, such as the keyboard, mouse, and memory cards. Accordingly, the present invention is directed to a USB hub with a USB powered speaker which comprises such a control circuit.

According to an embodiment of the present invention, a USB hub with a USB powered speaker is provided. This combinational apparatus comprises a USB hub controller, an amplifier stage and a volume controller. The USB hub controller controls a first USB socket and a second USB socket. The first USB socket connects an upstream USB device providing a voltage source. The second USB socket connects a downstream USB device powered by the voltage source. The amplifier stage is also powered by the same voltage source and drives a speaker according to an audio input signal. The volume controller provides a volume signal to control the gain of the amplifier stage. When the total current output by the voltage source is larger than a predetermined value, the volume signal changes in response to the total current.

In an embodiment of the present invention, the gain of the amplifier stage is an increasing function of the signal level of the volume signal. Besides, when the total current is larger than the predetermined value, the signal level of the volume signal is a decreasing function of the total current.

In an embodiment of the present invention, the volume controller comprises a voltage divider and a current limit circuit. The voltage divider comprises a first resistor coupled to a first reference voltage and a second resistor coupled between the first resistor and a ground. The volume signal is provided at the connection point of the first resistor and the second resistor. The current limit circuit is coupled between the connection point and the ground. The current limit circuit is equivalent to an open circuit when the total current is smaller than the predetermined value. On the other hand, the current limit circuit has a finite equivalent resistance when the total current is larger than the predetermined value, and the equivalent resistance changes in response to the total current.

In an embodiment of the present invention, the equivalent resistance of the current limit circuit is a decreasing function of the total current.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram showing an apparatus comprising a conventional USB hub and a USB-powered speaker.

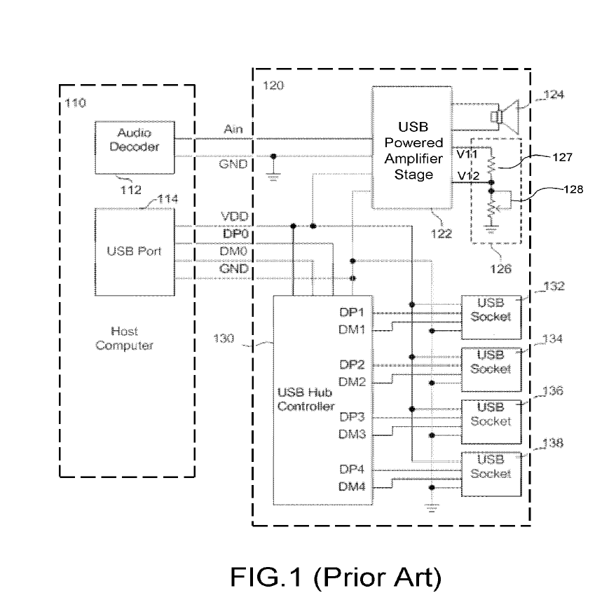

FIG. 2 is a schematic diagram showing an apparatus comprising a USB hub and a USB-powered speaker according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

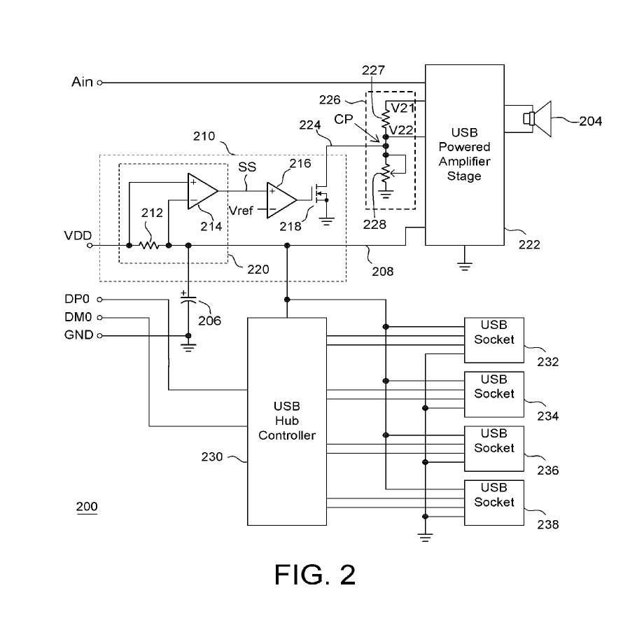

FIG. 2 is a schematic diagram showing the apparatus 200 comprising a USB hub and a USB-powered speaker according to an embodiment of the present invention. Apparatus 200 comprises USB hub controller 230, amplifier stage 222 and a volume controller circuit (210 and 226).

USB hub controller 230 controls an upstream USB socket consisting of the terminals VDD, DP0, DM0 and GND. The upstream USB socket is for connecting an upstream USB device providing the voltage source VDD. For example, the upstream USB device may be a host computer. USB hub controller 230 also controls the downstream USB sockets 232-238. The downstream USB sockets are used for connecting downstream USB devices powered by voltage source VDD. For example, the downstream USB devices may be peripherals of the host computer, such as keyboard, mouse and portable storage devices.

Amplifier stage 222 drives speaker 204 according to audio input signal Ain. Amplifier stage 222 is also powered by voltage source VDD. In this embodiment, amplifier stage 222 is a class-D audio power amplifier.

The volume controller (210 and 226) provides volume signal V22 to control the gain of amplifier stage 222. Volume signal V22 changes in response to the total current output by voltage source VDD when the total current is larger than a predetermined value (0.5 A in this embodiment). The total current is the sum of the current consumption of amplifier stage 222, USB hub controller 230 and the downstream USB devices connected to downstream USB sockets 232-238. In this embodiment, the gain of amplifier stage 222 is an increasing function of the signal level of volume signal V22. To prevent overload when the total current is larger than the predetermined value, the power consumption of amplifier stage 222 has to be reduced in order to maintain the power supplied to the downstream USB devices. That means the signal level of volume signal V22 has to be a decreasing function of the total current.

The volume controller comprises voltage divider 226 and current limit circuit 210. Voltage divider 226 comprises resistors 227 and 228. Resistor 227 is coupled to reference voltage V21. Resistor 228 is coupled between resistor 227 and the ground. Volume signal V22 is provided at the connection point (CP) of resistors 227 and 228. In this embodiment, reference voltage V21 is provided by amplifier stage 222, and resistor 228 is a variable resistor. The voltage level of volume signal V22 can be controlled by adjusting the resistance of resistor 228, thus controlling the gain and volume output level of amplifier stage 222.

Current limit circuit 210 is coupled between connection point CP and the ground. Current limit circuit 210 is equivalent to an open circuit when the total current is smaller than the predetermined value. On the other hand, current limit circuit 210 has a finite equivalent resistance when the total current is larger than the predetermined value, and the equivalent resistance changes in response to the total current. In this embodiment, the equivalent resistance is a decreasing function of the total current.

To implement the equivalent open circuit and the equivalent resistance, current limit circuit 210 comprises current sensor 220, operational amplifier 216 and N-channel metal oxide semiconductor field effect transistor (MOSFET) 218. Current sensor 220 provides sensor signal SS according to the total current. Operational amplifier 216 receives sensor signal SS and reference voltage Vref as input. MOSFET 218 is coupled between connection point CP and the ground. The gate terminal of MOSFET 218 is driven by operational amplifier 216.

Current sensor 220 comprises operational amplifier 214 and resistor 212. Operational amplifier 214 provides sensor signal SS. Resistor 212 is coupled to voltage source VDD and is also coupled between the two input terminals of operational amplifier 214. As can be seen in FIG. 2, the total current is drawn from voltage source VDD and through resistor 212. Consequently, sensor signal SS is the amplified result of the voltage across resistor 212, which is directly proportional to the total current. Operational amplifier 216 receives sensor signal SS and reference voltage Vref as input. Reference voltage Vref is chosen according to the predetermined value so that operational amplifier 216 turns on MOSFET 218 when the total current is larger than the predetermined value. Once MOSFET 218 is turned on, the resistance of MOSFET 218 becomes smaller as the total current becomes larger.

The combinational apparatus 200 further comprises capacitor 206. The major purpose of capacitor 206 is noise filtering.

If the total current is less than the predetermined value (0.5 A in this embodiment), then operational amplifier 216 outputs a low voltage signal. MOSFET 218 is kept in an off-state. Current limit circuit 210 is equivalent to an open circuit. The gain and the power consumption of amplifier stage 222 are not affected by the total current.

On the other hand, if the total current consumption of amplifier stage 222 and the other connected USB peripherals begins to exceed the predetermined value, then the output of operational amplifier 216 begins to rise accordingly. This eventually turns on MOSFET 218, making it a low resistance path in parallel with resistor 228. Since the resistance of resistor 227 is fixed, the low resistance of MOSFET 218 reduces the signal level of volume signal V22. This in turn rolls back the gain and the power consumption of amplifier stage 222.

The more tendencies the total current is to exceed the predetermined value, the higher the voltage which operational amplifier 216 will provide to MOSFET 218, thus the lower the resistance of MOSFET 218 appears to voltage divider 226. In such cases, the gain and power consumption of amplifier stage 222 roll back to counter the increase of the total current.

If the loop gain is sufficiently large, the close-loop current limiting scheme of current limit circuit 210 will reach an equilibrium point where the total current is regulated at exactly the predetermined value. In other words, the other USB peripherals can together draw up to a current of 0.5 A. If there is any left-over, the remainder is automatically made available to amplifier stage 222 of the USB-powered speaker.

In the case the total current drops below the predetermined value, MOSFET 218 will be turned off and return to its high-impedance state. Amplifier stage 222 will resume its original volume control setting and power consumption accordingly.

Please note that the focus of the present invention is the closed-loop control mechanism which reduces the power consumption of amplifier stage 222 to counter the increase of the total current when the total current consumption exceeds the predetermined limit. Although the closed-loop control mechanism of the above embodiment is implemented through the change of the equivalent resistance of current limit circuit 210, the present invention is not limited to such an implementation. For example, the closed-loop control mechanism can be implemented by digital circuit design as well.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A USB hub with a USB powered speaker, comprising:
a USB hub controller for controlling a first USB socket for connecting an upstream USB device providing a voltage source, and for controlling a second USB socket for connecting a downstream USB device powered by the voltage source;
an amplifier stage powered by the voltage source and for driving a speaker according to an audio input signal; and
a volume controller for providing a volume signal to control the gain of the amplifier stage, wherein the volume signal changes in response to the total current output by the voltage source when the total current is larger than a predetermined value.

2. The USB hub with the USB powered speaker of claim 1, wherein the gain of the amplifier stage is an increasing function of the signal level of the volume signal, and, when the total current is larger than the predetermined value, the signal level of the volume signal is a decreasing function of the total current.

3. The USB hub with the USB powered speaker of claim 1, wherein the volume controller comprises:
a voltage divider comprising:
a first resistor coupled to a first reference voltage;
a second resistor coupled between the first resistor and a ground, wherein the volume signal is provided at the connection point of the first resistor and the second resistor; and
a current limit circuit coupled between the connection point and the ground, equivalent to an open circuit when the total current is smaller than the predetermined value, having a finite equivalent resistance when the total current is larger than the predetermined value, wherein the equivalent resistance changes in response to the total current.

4. The USB hub with the USB powered speaker of claim 3, wherein the first reference voltage is provided by the amplifier stage.

5. The USB hub with the USB powered speaker of claim 3, wherein the second resistor is a variable resistor.

6. The USB hub with the USB powered speaker of claim 3, wherein the equivalent resistance is a decreasing function of the total current.

7. The USB hub with the USB powered speaker of claim 3, wherein the current limit circuit comprises:
a current sensor for providing a sensor signal according to the total current;
a first operational amplifier receiving the sensor signal and a second reference voltage; and
a MOSFET coupled between the connection point and the ground, the gate terminal of the MOSFET driven by the first operational amplifier.

8. The USB hub with the USB powered speaker of claim 7, wherein the MOSFET is an N-channel MOSFET.

9. The USB hub with the USB powered speaker of claim 7, wherein the current sensor comprises:
a second operational amplifier for providing the sensor signal; and
a third resistor coupled to the voltage source and coupled between the two input terminals of the second operational amplifier, wherein the total current is drawn from the voltage source through the third resistor.
